(19) United States
(12) Patent Application Publication
(10) Pub. No.: US 2013/0221804 A1
(43) Pub. Date: Aug. 29, 2013

(54) Sensor Element, Sensor Device, And Electronic Apparatus

(71) Applicant: Seiko Epson Coporation, (US)

(72) Inventor: Fumio ICHIKAWA, Suwa (JP)

(73) Assignee: SEIKO EPSON CORPORATION, Tokyo (JP)

(21) Appl. No.: 13/771,489

(22) Filed: Feb. 20, 2013

(30) Foreign Application Priority Data
Feb. 28, 2012 (JP) 2012-042548

(51) Int. Cl. H01L 41/113

(52) U.S. Cl. CPC H01L 41/1132
USPC 310/323.21

(57) ABSTRACT

A sensor element includes a base, vibrating arms for detection extended from the base, and first to fourth detecting sections provided in the vibrating arms for detection. The first to fourth detecting sections respectively include lower electrode layers, upper electrode layers, and piezoelectric layers. The lower electrode layers of the first and second detecting sections are electrically connected to each other. The lower electrodes of the third and fourth detecting sections are electrically connected to each other.

### BACKGROUND

1. Technical Field

The present invention relates to a sensor element, a sensor device, and an electronic apparatus.

2. Related Art

As a sensor element, there is known, for example, a sensor used for, for example, vehicle body control in a vehicle, own vehicle position detection of a car navigation system, and vibration control correction (so-called camera shake correction) of a digital camera, a video camera, and the like and configured to detect physical quantities such as angular velocity and acceleration. As the sensor, for example, an angular velocity sensor (a vibration gyro sensor) is known (see, for example, WO2003/104749 (Patent Literature 1)).

For example, the angular velocity sensor described in Patent Literature 1 includes a tuning fork including two arms and a connecting section that connects one ends of the two arms. In the angular velocity sensor described in Patent Literature 1, the tuning fork is made of a non-piezoelectric material. A driving section and a detecting section, each formed by interposing a piezoelectric film between a pair of electrodes, are provided in each of the arms.

In the angular velocity sensor described in Patent Literature 1, the arm is subjected to bending vibration (driven) by applying a voltage between the pair of electrodes of the driving section. In a driven state of the arm, when the arm receives angular velocity around an axis extending along an extending direction of the arm, the arm is distorted by a Coriolis force in a direction orthogonal to the direction of the driving. Charges corresponding to an amount of the distortion are detected from the pair of electrodes of the detecting section. Angular velocity can be detected on the basis of the detected charges.

In the past, in such an angular velocity sensor, the pair of electrodes of the detecting section provided in one arm and the pair of electrodes of the detecting section provided in the other arm are independent from each other. The two detecting sections are electrically connected in parallel to detect charges from the detecting sections.

Therefore, noise due to parasitic capacitance generated between the pairs of electrodes of the detecting sections is large, leading to deterioration in detection sensitivity.

### SUMMARY

An advantage of some aspects of the invention is to provide a sensor element having excellent detection sensitivity and provide a sensor device and an electronic apparatus including such a sensor element and excellent in reliability.

The invention can be implemented as the following forms or application examples.

### Application Example 1

This application example of the invention is directed to a sensor element including: a base; a vibrating arm for detection extended from the base; and a first detecting section and a second detecting section provided in the vibrating arm for detection and configured to output charges according to vibration of the vibrating arm for detection. The first detecting section includes a first lower electrode layer, a first upper electrode layer, and a first piezoelectric layer provided between the first lower electrode layer and the first upper electrode layer. The first lower electrode layer is provided on the vibrating arm for detection side. The second detecting section includes a second lower electrode layer, a second upper electrode layer, and a second piezoelectric layer provided between the second lower electrode layer and the second upper electrode layer. The second lower electrode layer is provided on the vibrating arm for detection side. The first lower electrode layer and the second lower electrode layer or the first upper electrode layer and the second upper electrode layer are electrically connected.

With the sensor element configured as explained above, it is possible to electrically connect the first detecting section and the second detecting section in series and detect charges from the detecting sections. Therefore, compared with parasitic capacitance generated when the first detecting section and the second detecting section are electrically connected in parallel as in the past, it is possible to reduce the parasitic capacitance to about a quarter. As a result, it is possible to improve the detection sensitivity of the sensor element.

### Application Example 2

In the sensor element according to the application example, it is preferable that the first lower electrode layer and the second lower electrode layer are electrically connected to each other by the vibrating arm for detection.

Consequently, with a relatively simple configuration, it is possible to electrically connect the first detecting section and the second detection in series.

### Application Example 3

In the sensor element according to the application example, it is preferable that the sensor element further includes: a vibrating arm for driving extended from the base; and a driving section provided in the vibrating arm for driving and configured to subject the vibrating arm for driving to bending vibration.

Consequently, it is unnecessary to provide a driving section in the vibrating arm in which the first detecting section and the second detecting section are provided. Therefore, with a relatively simple configuration, it is possible to electrically connect the first lower electrode layer and the second lower electrode layer to each other via the vibrating arm.

### Application Example 4

This application example of the invention is directed to a sensor element including: a base; a first vibrating arm and a second vibrating arm extended from the base; a first detecting section provided in the first vibrating arm and configured to output charges according to vibration of the first vibrating arm; and a second detecting section provided in the second vibrating arm and configured to output charges according to vibration of the second vibrating arm. The first detecting section includes a first lower electrode layer, a first upper electrode layer, and a first piezoelectric layer provided between the first lower electrode layer and the first upper electrode layer. The first lower electrode layer is provided on the first vibrating arm side. The second detecting section includes a second lower electrode layer, a second upper electrode layer, and a second piezoelectric layer provided between the second lower electrode layer and the second upper electrode layer. The first lower electrode layer is provided on the first vibrating arm side. The first lower electrode layer and the second lower electrode layer or the first upper electrode layer and the second upper electrode layer are electrically connected.

With the sensor element configured as explained above, it is possible to electrically connect the first detecting section and the second detecting section in series and detect charges from the detecting sections. Therefore, compared with parasitic capacitance generated when the first detecting section and the second detecting section are electrically connected in parallel as in the past, it is possible to reduce the parasitic capacitance to about a quarter. As a result, it is possible to improve the detection sensitivity of the sensor element.

### Application Example 5

In the sensor element according to the application example, it is preferable that the first lower electrode layer and the second lower electrode layer are electrically connected to each other by the base.

Consequently, with a relatively simple configuration, it is possible to electrically connect the first detecting section and the second detecting section in series.

### Application Example 6

In the sensor element according to the application example, it is preferable that the sensor element further includes: a first driving section provided in the first vibrating arm and configured to subject the first vibrating arm to bending vibration; and a second driving section provided in the second vibrating arm and configured to subject the second vibrating arm to bending vibration.

Consequently, the driving sections and the detecting sections are respectively provided in the first vibrating arm and the second vibrating arm. In such a case, an effect realized by electrically connecting the first lower electrode layer and the second lower electrode layer each other via the base is conspicuous.

### Application Example 7

In the sensor element according to the application example, it is preferable that the sensor element further includes: a first terminal for detection provided in the base and electrically connected to the first upper electrode layer; and a second terminal for detection provided in the base and electrically connected to the second upper electrode layer.

Consequently, with a relatively simple configuration, it is possible to electrically connect the first detecting section and the second detecting section in series and detect charges from the detecting sections.

### Application Example 8

This application example of the invention is directed to a sensor device including the sensor element according to the aspect explained above.

Consequently, it is possible to provide a sensor device excellent in reliability.

### Application Example 9

In the sensor device according to the application example, it is preferable that the sensor device further includes a detecting circuit configured to detect charges from the first detecting section and the second detecting section. The first lower electrode layer and the second lower electrode layer are electrically connected to each other. The first upper electrode layer and the second upper electrode layer are electrically connected to the detecting circuit.

Consequently, it is possible to electrically connect the first detecting section and the second detecting section to the detecting circuit in series and detect charges from the detecting sections.

### Application Example 10

This application example of the invention is directed to an electronic apparatus including the sensor element according to the aspect explained above.

Consequently, it is possible to provide an electronic apparatus excellent in reliability.

### BRIEF DESCRIPTION OF THE DRAWINGS

The invention will be described with reference to the accompanying drawings, wherein like numbers reference like elements.

FIG. 1 is a sectional view showing a schematic configuration of a sensor device according to a first embodiment of the invention.

FIG. 2 is a plan view of the sensor device shown in FIG. 1.

FIG. 3 is a plan view of a sensor element of the sensor device shown in FIG. 1.

FIG. 4A is a sectional view taken along line A-A in FIG. 3.

FIG. 4B is a sectional view taken along line B-B in FIG. 3.

FIGS. 5A and 5B are plan views for explaining driving of the sensor element shown in FIG. 3.

FIG. 6A is a block diagram for explaining detecting sections of the sensor element shown in FIG. 3.

FIG. 6B is a block diagram for explaining detecting sections of a sensor element in the past.

FIG. 7 is a plan view of a sensor element of a sensor device according to a second embodiment of the invention.

FIG. 8A is a sectional view taken along line B-B in FIG. 7.

FIG. 8B is a sectional view taken along line C-C in FIG. 7.

FIG. 9 is a block diagram for explaining detecting sections of the sensor element shown in FIG. 7.

FIG. 10 is a perspective view showing the configuration of a mobile (or notebook) personal computer to which an electronic apparatus according to an embodiment of the invention is applied.

FIG. 11 is a perspective view showing the configuration of a cellular phone (including a PHS) to which the electronic apparatus according to the embodiment of the invention is applied.

FIG. 12 is a perspective view showing the configuration of a digital still camera to which the electronic apparatus according to the embodiment of the invention is applied.

### DESCRIPTION OF EXEMPLARY EMBODIMENTS

Sensor elements, sensor devices, and electronic apparatuses according to embodiments of the invention are explained in detail below with reference to the accompanying drawings.

### First Embodiment

### Sensor Device

First, a sensor device according to a first embodiment of the invention (a sensor device including a sensor element according to the first embodiment of the invention) is explained.

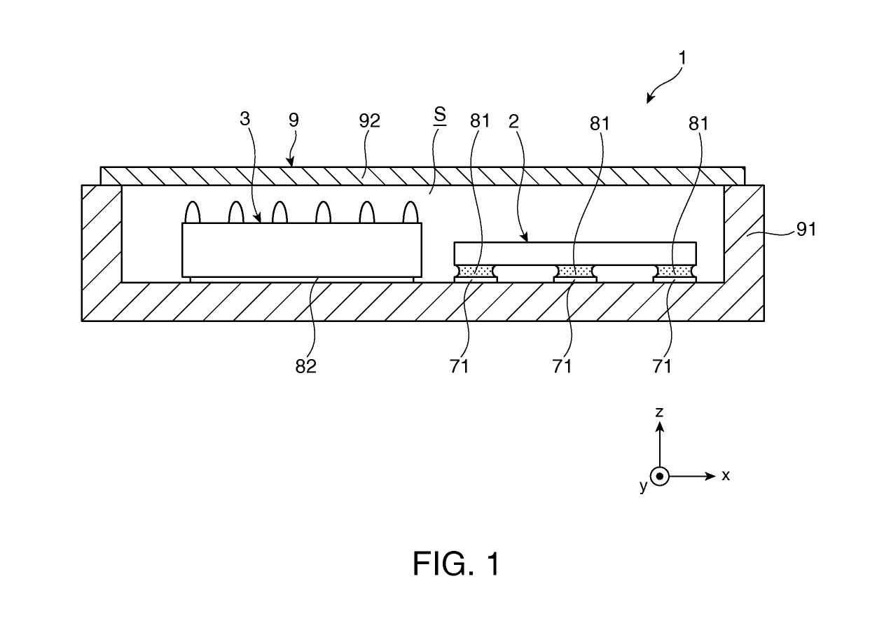

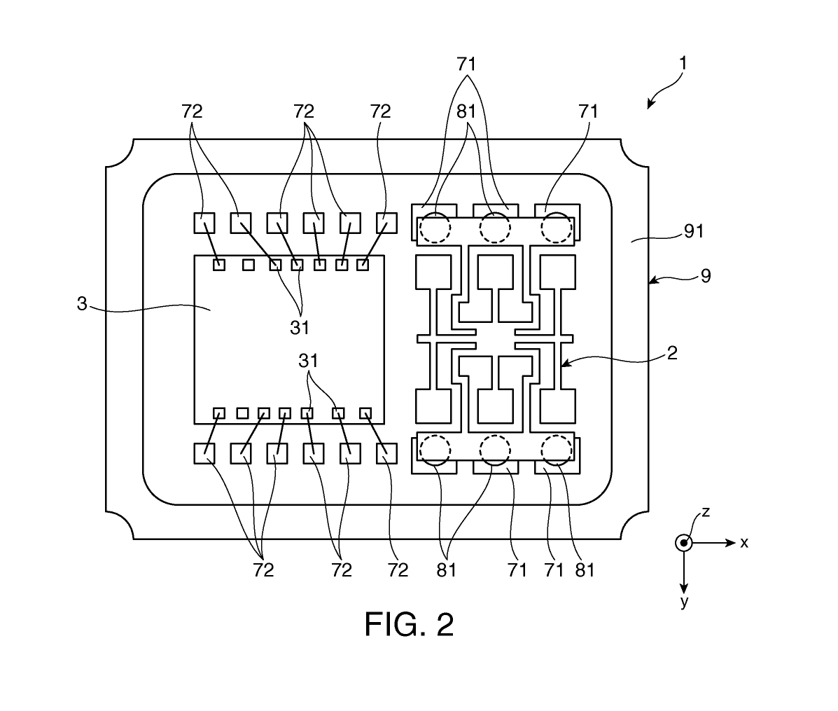

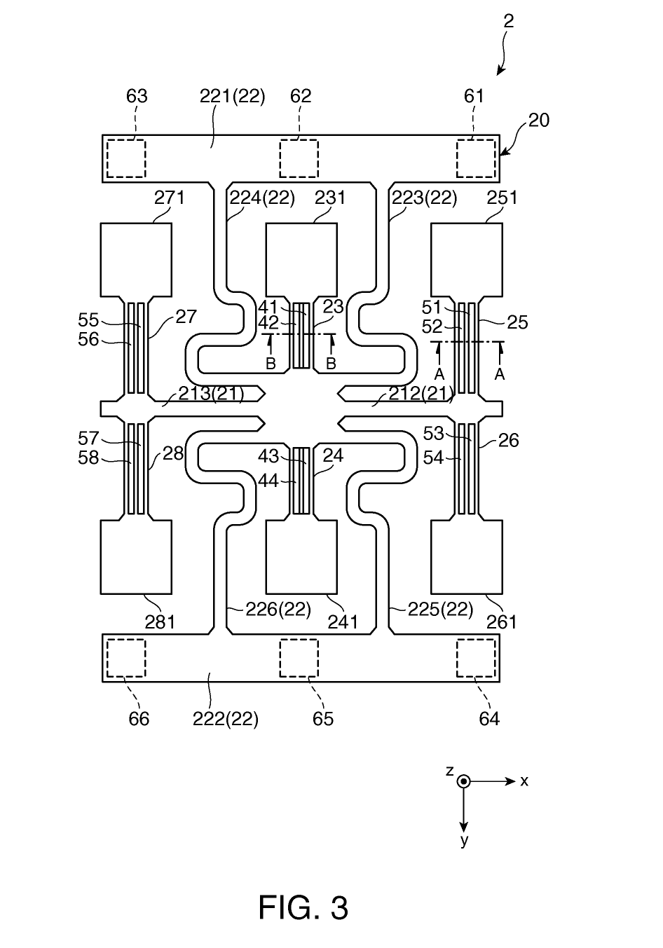

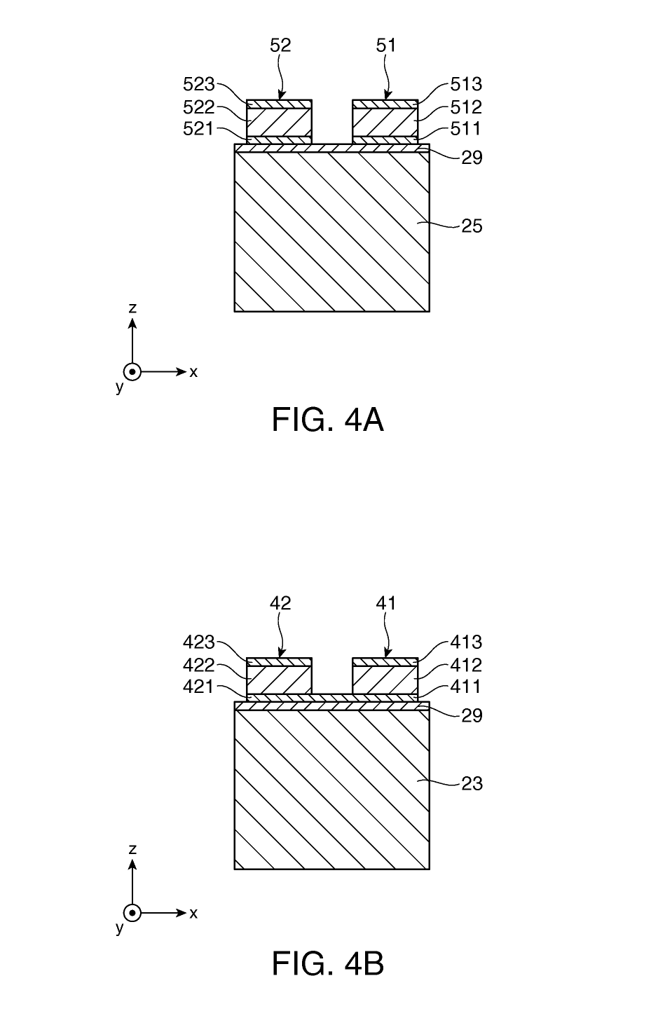

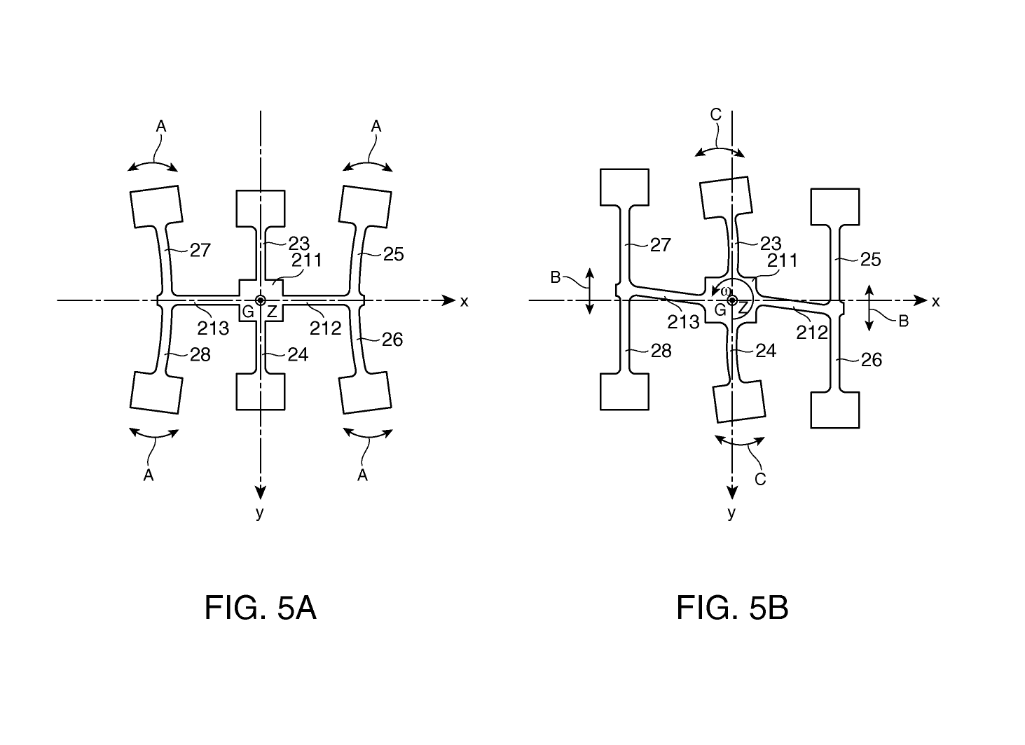

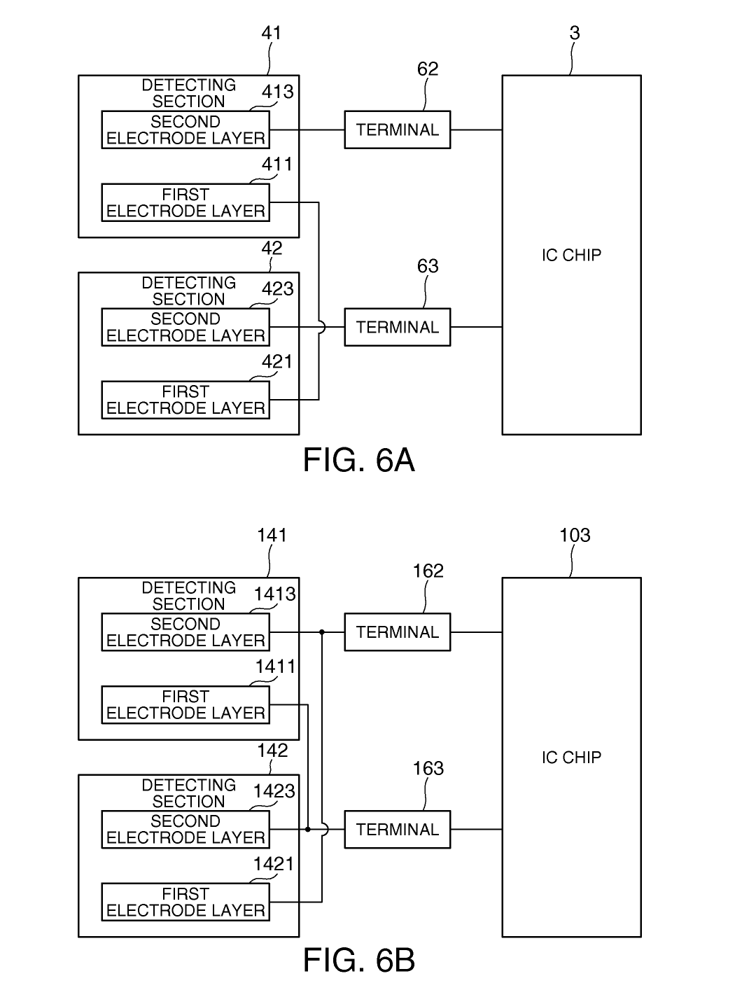

FIG. 1 is a sectional view showing a schematic configuration of the sensor device according to the first embodiment of the invention. FIG. 2 is a plan view of the sensor device shown in FIG. 1. FIG. 3 is a plan view of a sensor element of the sensor device shown in FIG. 1. FIG. 4A is a sectional view taken along line A-A in FIG. 3. FIG. 4B is a sectional view taken along line B-B in FIG. 3. FIGS. 5A and 5B are plan views for explaining driving of the sensor element shown in FIG. 3. FIG. 6A is a block diagram for explaining detecting sections of the sensor element shown in FIG. 3. FIG. 6B is a block diagram for explaining detecting sections of a sensor element in the past.

In FIGS. 1 to 5, for convenience of explanation, an x axis, a y axis, and a z axis are shown as three axes orthogonal to one another. Distal end sides of arrows of the axes shown in the figures are represented as “+ side” and proximal end sides of the arrows are represented as “− side”. In the following explanation, a direction parallel to the x axis is referred to as “x-axis direction”. A direction parallel to the y axis is referred to as “y-axis direction”. A direction parallel to the z axis is referred to as “z-axis direction”. A+z side (the upper side in FIG. 1) is referred to as “upper”. A −z side (the lower side in FIG. 1) is referred to as “lower”.

A sensor device 1 shown in FIGS. 1 and 2 is a gyro sensor that detects angular velocity. The sensor device 1 includes a sensor element (a vibrating device) 2, an IC chip 3, and a package 9 that houses the sensor element 2 and the IC chip 3. The IC chip 3 may be omitted or may be provided on the outside of the package 9.

### Sensor Element

The sensor element 2 is a sensor element (a vibrating element) of an “out-of-plane detection type” that detects angular velocity around the z axis. The sensor element 2 includes, as shown in FIG. 3, a vibrating body 20 including a plurality of vibrating arms, and a plurality of detecting sections 41 to 44, a plurality of driving sections 51 to 58, and a plurality of terminals 61 to 66 provided on the surface of the vibrating body 20.

The sections included in the sensor element 2 are sequentially explained below in detail.

### Vibrating Body

First, the vibrating body 20 is explained. The vibrating body 20 has structure called double-T type. Specifically, the vibrating body 20 includes a base 21, a supporting section 22 that supports the base 21, and two vibrating arms for detection (second vibrating arms) 23 and 24 and four vibrating arms for driving (first vibrating arms) 25 to 28 extending from the base 21.

The base 21 includes a main body section 211 and a pair of coupling arms 212 and 213 extending from the main body section 211 to opposite sides each other along the x-axis direction.

The supporting section 22 includes a pair of fixed sections 221 and 222 fixed to the package 9, a pair of beam sections 223 and 224 that couple the fixed section 221 and the main body section 211 of the base 21, and a pair of beam sections 225 and 226 that couple the fixed section 222 and the main body section 211 of the base 21.

The vibrating arms for detection 23 and 24 extend from the main body section 211 of the base 21 to opposite sides from each other along the y-axis direction.

The vibrating arms for driving 25 and 26 extend from the distal end of the coupling arm 212 of the base 21 to opposite sides each other along the y-axis direction.

The vibrating arms for driving 27 and 28 extend from the distal end of the coupling arm 213 of the base 21 to opposite sides each other along the y-axis direction.

In this embodiment, a weight section (a hammer head) 231 larger in width than the proximal end of the vibrating arm for detection 23 is provided at the distal end of the vibrating arm for detection 23. Similarly, a weight section 241 is provided at the distal end of the vibrating arm for detection 24. A weight section 251 is provided at the distal end of the vibrating arm for driving 25. A weight section 261 is provided at the distal end of the vibrating arm for driving 26. A weight section 271 is provided at the distal end of the vibrating arm for driving 27. A weight section 281 is provided at the distal end of the vibrating arm for driving 28. It is possible to improve the detection sensitivity of the sensor element 2 by providing such weight sections.

A material forming the vibrating body 20 is not specifically limited as long as the material can display a desired vibration characteristic. Various piezoelectric materials and various non-piezoelectric materials can be used.

Examples of a piezoelectric material forming the vibrating body 20 include crystal, lithium tantalate, lithium niobate, lithium borate, and barium titanate. In particular, crystal (an X-cut substrate, an AT-cut substrate, a Z-cut substrate, etc.) is desirable as the piezoelectric material forming the vibrating body 20. When the vibrating body 20 is formed of crystal, the vibrating body 20 can be excellent in a vibration characteristic (in particular, a frequency temperature characteristic). Further, the vibrating body 20 can be formed at high dimension accuracy by etching.

Examples of a non-piezoelectric material forming the vibrating body 20 include silicon and quartz. In particular, silicon is desirable as the non-piezoelectric material forming the vibrating body 20. When the vibrating body 20 is formed of silicon, the vibrating body 20 having an excellent vibration characteristic can be realized at relatively low costs. Further, the vibrating body 20 can be formed at high dimension accuracy by etching using a publicly-known micro machining technique.

In this embodiment, as shown in FIGS. 4A and 4B, an insulator layer 29 is provided on the upper surface of the vibrating body 20. Consequently, it is possible to prevent a short circuit among the sections of the driving sections 51 to 58 and the detecting sections 41 and 42.

The insulator layer 29 is formed of, for example, SiO₂ (silicon oxide), AlN (aluminum nitride), or SiN (silicon nitride). A method of forming the insulator layer 29 is not specifically limited. A publicly-known film forming method can be used. For example, when the insulator layer 29 is formed of SiO₂, it is possible to form the insulator layer 29 by thermally oxidizing the upper surface of the vibrating body 20.

### Driving Sections

The driving sections 51 to 58 are explained. The driving sections 51 and 52 are provided on the vibrating arm for driving 25 of the vibrating body 20. The driving sections 53 and 54 are provided on the vibrating arm for driving 26 of the vibrating body 20. The driving sections 55 and 56 are provided on the vibrating arm for driving 27 of the vibrating body 20. The driving sections 57 and 58 are provided on the vibrating arm for driving 28 of the vibrating body 20.

The pair of driving sections 51 and 52 subject the vibrating arm for driving 25 to bending vibration in the x-axis direction through energization. Similarly, the pair of driving sections 53 and 54 subject the vibrating arm for driving to bending vibration in the x-axis direction through energization. The pair of driving sections 55 and 56 subject the vibrating arm for driving 27 to bending vibration in the x-axis direction through energization. The pair of driving sections 57 and 58 subject the vibrating arm for driving 28 to bending vibration in the x-axis direction through energization.

More specifically, the driving section 51 is provided on one side (the right side in FIG. 3) and the driving section 52 is provided on the other side (the left side in FIG. 3) in the width direction of the vibrating arm for driving 25 (the x-axis direction). Similarly, the driving section 53 is provided on one side (the right side in FIG. 3) and the driving section 54 is provided on the other side (the left side in FIG. 3) in the width direction of the vibrating arm for driving 26 (the x-axis direction). The driving section 55 is provided on one side (the right side in FIG. 3) and the driving section 56 is provided on the other side (the left side in FIG. 3) in the width direction of the vibrating arm for driving 27 (the x-axis direction). The driving section 57 is provided on one side (the right side in FIG. 3) and the driving section 58 is provided on the other side (the left side in FIG. 3) in the width direction of the vibrating arm for driving 28 (the x-axis direction).

Each of the driving sections 51 to 58 is a piezoelectric element formed to expand and contract in the y-axis direction by energization. Each of the driving sections 51 and 52 subjects the vibrating arm for driving 25 to driving vibration (bending vibration in the x-axis direction) through energization. Similarly, each of the driving sections 53 and 54 subjects the vibrating arm for driving 26 to driving vibration (bending vibration in the x-axis direction) through energization. Each of the driving sections 55 and 56 subjects the vibrating arm for driving 27 to driving vibration (bending vibration in the x-axis direction) through energization. Each of the driving sections 57 and 58 subjects the vibrating arm for driving 28 to driving vibration (bending vibration in the x-axis direction) through energization.

Since the driving sections 51 to 58 are used, even if the vibrating arms for driving 25 to 28 do not have piezoelectricity by themselves or even if the vibrating arms for driving 25 to 28 have piezoelectricity by themselves but the directions of polarization axes and crystal axes thereof are not suitable for the bending vibration in the x-axis direction, it is possible to relatively easily and efficiently subject the vibrating arms for driving 25 to 28 to bending vibration (driving vibration) in the x-axis direction. Since the presence or absence of piezoelectricity and the directions of the polarization axes and the crystal axes of the vibrating arms for driving 25 to 28 do not matter, a material forming the vibrating arms for driving 25 to 28 can be selected from a wider range of materials. Therefore, it is possible to relatively easily realize the vibrating body 20 having a desired vibration characteristic.

The configuration of the driving sections 51 and 52 is explained in detail below. The configuration of the driving sections 53 to 58 is the same as the configuration of the driving sections 51 and 52 (the driving sections 53 to 58 have a laminated structure same as the laminated structure of the driving sections 51 and 52). Therefore, explanation of the configuration of the driving sections 53 to 58 is omitted.

As shown in FIG. 4A, the driving section 51 is configured by laminating a first electrode layer 511, a piezoelectric layer (a piezoelectric thin film) 512, and a second electrode layer 513 on the vibrating arm for driving 25 in this order.

Similarly, the driving section 52 is configured by laminating a first electrode layer 521, a piezoelectric layer (a piezoelectric thin film) 522, and a second electrode layer 523 on the vibrating arm for driving 25 in this order.

Each of the first electrode layers 511 and 521 can be formed of, for example, a metal material such as gold (Au), a gold alloy, platinum (Pt), aluminum (Al), an aluminum alloy, silver (Ag), a silver alloy, chrome (Cr), a chrome alloy, copper (Cu), molybdenum (Mo), niobium (Nb), tungsten (W), iron (Fe), titanium (Ti), cobalt (Co), zinc (Zn), or zirconium (Zr) or a transparent electrode material such as ITO or ZnO.

Among these materials, as a material forming each of the first electrode layers 511 and 521, it is desirable to use metal (gold or the gold alloy) containing gold as a main material or platinum. It is more desirable to use metal (in particular, gold) containing gold as a main material.

Since Au is excellent in electrical conductivity (has small electric resistance) and excellent in resistance against oxidation, Au is suitable as an electrode material. Au can be easily patterned by etching compared with Pt. Further, it is possible to improve the orientation of the piezoelectric layers 512 and 522 by forming the first electrode layers 511 and 512 with gold or a gold alloy.

Average thickness of each of the first electrode layers 511 and 521 is not specifically limited. However, for example, the average thickness is desirably about 1 to 300 nm and more desirably 10 to 200 nm. Consequently, it is possible to improve the electrical conductivity of the first electrode layers 511 and 512 while preventing the first electrode layers 511 and 521 from adversely affecting a driving characteristic of the driving sections 51 and 52 and a vibration characteristic of the vibrating arm for driving 25.

A base layer having a function of preventing the first electrode layers 511 and 521 from peeling from the vibrating arm for driving 25 may be provided between the first electrode layers 511 and 521 and the vibrating arm for driving 25.

The base layer is formed of, for example, Ti or Cr.

Examples of a material (a piezoelectric material) forming each of the piezoelectric layers 512 and 522 include zinc oxide (ZnO), aluminum nitride (AlN), lithium tantalate (LiTaO₃), lithium niobate (LiNbO₃), potassium niobate (KNbO₃), lithium tetraborate (Li₂B₄O₇), barium titanate (BaTiO₃), and PZT (lead zirconate titanate).

Among the materials, as the material forming each of the piezoelectric layers 512 and 522, it is desirable to use PZT. PZT is excellent in c-axis orientation. Therefore, it is possible to reduce a CI value of the sensor element 2 by forming the piezoelectric layers 512 and 522 using PZT as a main material. These materials can be deposited by a reactive sputtering method.

Average thickness of the piezoelectric layers 512 and 522 is desirably 50 to 3000 nm and more desirably 200 to 2000 nm. Consequently, it is possible to improve the driving characteristic of the driving sections 51 and 52 while preventing the piezoelectric layers 512 and 522 from adversely affecting the vibration characteristic of the vibrating arm for driving 25.

Each of the second electrode layers 513 and 523 can be formed of, for example, a metal material such as gold (Au), a gold alloy, platinum (Pt), aluminum (Al), an aluminum alloy, silver (Ag), a silver alloy, chrome (Cr), a chrome alloy, copper (Cu), molybdenum (Mo), niobium (Nb), tungsten (W), iron (Fe), titanium (Ti), cobalt (Co), zinc (Zn), or zirconium (Zr) or a transparent electrode material such as ITO or ZnO.

An average thickness of each of the second electrode layers 513 and 523 is not specifically limited. However, for example, the average thickness is desirably about 1 to 300 nm and more desirably 10 to 200 nm. Consequently, it is possible to improve the electrical conductivity of the second electrode layers 513 and 523 while preventing the second electrode layers 513 and 523 from adversely affecting the driving characteristic of the driving sections 51 and 52 and the vibration characteristic of the vibrating arm for driving 25.

An insulator layer (an insulative protection layer) having a function of protecting the piezoelectric layer 512 and preventing a short circuit between the first electrode layer 511 and the second electrode layer 513 may be provided between the piezoelectric layer 512 and the second electrode layer 513. Similarly, an insulator layer may be provided between the piezoelectric layer 522 and the second electrode layer 523.

The insulator layer is formed of, for example, SiO₂ (silicon oxide), AlN (aluminum nitride), or SiN (silicon nitride).

A base layer having a function of preventing the second electrode layer 513 from peeling from the piezoelectric layer 512 (when the insulator layer is provided, the insulator layer) may be provided between the piezoelectric layer 512 and the second electrode layer 513. Similarly, a base layer may be provided between the piezoelectric layer 522 and the second electrode layer 523.

The base layer is formed of, for example, Ti or Cr.

In the driving section 51 configured as explained above, when a voltage is applied between the first electrode layer 511 and the second electrode layer 513, an electric field in the z-axis direction is generated in the piezoelectric layer 512. The piezoelectric layer 512 expands or contracts in the y-axis direction. Similarly, in the driving section 52, when a voltage is applied between the first electrode layer 521 and the second electrode layer 523, an electric field in the z-axis direction is generated in the piezoelectric layer 522. The piezoelectric layer 522 expands or contracts in the y-axis direction.

At this point, when one of the driving sections 51 and 52 is caused to expand in the y-axis direction, the other is caused to contract in the y-axis direction. Consequently, the vibrating arm for driving 25 can be subjected to bending vibration in the x-axis direction.

Similarly, the vibrating arm for driving 26 can be subjected to bending vibration in the x-axis direction by the driving sections 53 and 54. The vibrating arm for driving 27 can be subjected to bending vibration in the x-axis direction by the driving sections 55 and 56. The vibrating arm for driving 28 can be subjected to bending vibration in the x-axis direction by the driving sections 57 and 58.

In the driving section 51, the first electrode layer 511 is electrically connected to the terminal 61 via a wire (not shown in the figure) and the second electrode layer 513 is electrically connected to the terminal 64 via a wire (not shown in the figure).

In the driving section 52, the first electrode layer 521 is electrically connected to the terminal 64 via a wire (not shown in the figure) and the second electrode layer 523 is electrically connected to the terminal 61 via a wire (not shown in the figure).

Similarly, in the driving section 53, the first electrode layer is electrically connected to the terminal 61 and the second electrode layer is electrically connected to the terminal 64. In the driving section 54, the first electrode layer is electrically connected to the terminal 64 and the second electrode layer is electrically connected to the terminal 61.

In the driving section 55, the first electrode layer is electrically connected to the terminal 64 and the second electrode layer is electrically connected to the terminal 61. In the driving section 56, the first electrode layer is electrically connected to the terminal 61 and the second electrode layer is electrically connected to the terminal 64.

In the driving section 57, the first electrode layer is electrically connected to the terminal 64 and the second electrode layer is electrically connected to the terminal 61. In the driving section 58, the first electrode layer is electrically connected to the terminal 61 and the second electrode layer is electrically connected to the terminal 64.

### Detecting Sections

The detecting sections 41 to 44 are explained. Each of the detecting sections 41 and 42 (a first detecting section and a second detecting section) is provided on the vibrating arm for detection 23 of the vibrating body 20. Each of the detecting sections 43 and 44 (a first detecting section and a second detecting section) is provided on the vibrating arm for detection 24 of the vibrating body 20.

The pair of detecting sections 41 and 42 detect bending vibration (so-called in-plane vibration) in the x-axis direction of the vibrating arm for detection 23. Similarly, the pair of detecting sections 43 and 44 detect bending vibration in the x-axis direction of the vibrating arm for detection 24.

More specifically, the detecting section 41 (the first detecting section) is provided on one side (the right side in FIG. 3) in the width direction of the vibrating arm for detection 23 (the x-axis direction). The detecting section 42 (the second detecting section) is provided on the other side (the left side in FIG. 3). Similarly, the detecting section 43 (the first detecting section) is provided on one side (the right side in FIG. 3) in the width direction of the vibrating arm for detection 24 (the x-axis direction). The detecting section 44 (the second detecting section) is provided on the other side (the left side in FIG. 3).

Each of the detecting sections 41 to 44 is a piezoelectric element configured to output charges by expanding and contracting in the y-axis direction. Each of the detecting sections 41 and 42 outputs charges according to the vibration (the bending vibration in the x-axis direction) of the vibrating arm for detection 23. Similarly, each of the detecting sections 43 and 44 outputs charges according to the vibration (the bending vibration in the x-axis direction) of the vibrating arm for detection 24.

Since the detecting sections 41 to 44 are used, even if the vibrating arms for detection 23 and 24 do not have piezoelectricity by themselves or even if the vibrating arms for detection 23 and 24 have piezoelectricity by themselves but the directions of polarization axes and crystal axes thereof are not suitable for detection of the bending vibration in the x-axis direction, it is possible to relatively easily and efficiently detect the bending vibration in the x-axis direction of the vibrating arms for detection 23 and 24. Since the presence or absence of piezoelectricity and the directions of the polarization axes and the crystal axes of the vibrating arms for detection 23 and 24 do not matter, a material forming the vibrating arms for detection 23 and 24 can be selected from a wider range of materials. Therefore, it is possible to relatively easily realize the vibrating body 20 having a desired vibration characteristic.

Each of the detecting sections 41 to 44 and 51 to 58 explained above is a piezoelectric element including a laminated structure configured by laminating a plurality of layers in the z-axis direction.

The configuration of the detecting sections 41 and 42 is explained in detail below. The configuration of the detecting sections 43 and 44 is the same as the configuration of the detecting sections 41 and 42 (the detecting sections 43 and 44 have a laminated structure same as the laminated structure of the detecting sections 41 and 42). Therefore, explanation of the configuration of the detecting sections 43 and 44 is omitted.

The detecting section 41 (the first detecting section) includes, as shown in FIG. 4B, a first electrode layer 411 (a first lower electrode layer), a second electrode layer 413 (a first upper electrode layer) provided on the opposite side of the vibrating arm for detection 23 with respect to the first electrode layer 411, and a piezoelectric layer 412 (a first piezoelectric layer) provided between the first electrode layer 411 and the second electrode layer 413. In other words, in the detecting section 41, the first electrode layer 411, the piezoelectric layer (a piezoelectric thin film) 412, and the second electrode layer 413 are laminated on the vibrating arm for detection 23 in this order.

Similarly, the detecting section 42 (the second detecting section) is configured by laminating a first electrode layer 421 (a second lower electrode layer), a piezoelectric layer (a piezoelectric thin film) 422 (a second piezoelectric layer), and a second electrode layer 423 (the second upper electrode layer) on the vibrating arm for detection 23 in this order.

Each of the first electrode layers 411 and 412 can be formed of, for example, a metal material such as gold (Au), a gold alloy, platinum (Pt), aluminum (Al), an aluminum alloy, silver (Ag), a silver alloy, chrome (Cr), a chrome alloy, copper (Cu), molybdenum (Mo), niobium (Nb), tungsten (W), iron (Fe), titanium (Ti), cobalt (Co), zinc (Zn), or zirconium (Zr) or a transparent electrode material such as ITO or ZnO.

Among these materials, as a material forming each of the first electrode layers 411 and 421, it is desirable to use metal (gold or the gold alloy) containing gold as a main material or platinum. It is more desirable to use metal (in particular, gold) containing gold as a main material.

Since Au is excellent in electrical conductivity (has small electric resistance) and excellent in resistance against oxidation, Au is suitable as an electrode material. Au can be easily patterned by etching compared with Pt. Further, it is possible to improve the orientation of the piezoelectric layers 412 and 422 by forming the first electrode layers 411 and 421 with the gold alloy.

Average thickness of each of the first electrode layers 411 and 421 is not specifically limited. However, for example, the average thickness is desirably about 1 to 300 nm and more desirably 10 to 200 nm. Consequently, it is possible to improve the electrical conductivity of the first electrode layers 411 and 421 while preventing the first electrode layers 411 and 421 from adversely affecting a detection characteristic of the detecting sections 41 and 42 and a vibration characteristic of the vibrating arm for detection 23.

A base layer having a function of preventing the first electrode layers 411 and 421 from peeling from the vibrating arm for detection 23 may be provided between the first electrode layers 411 and 421 and the vibrating arm for detection 23.

The base layer is formed of, for example, Ti or Cr.

Examples of a material (a piezoelectric material) forming each of the piezoelectric layers 412 and 422 include zinc oxide (ZnO), aluminum nitride (AlN), lithium tantalate (LiTaO₃), lithium niobate (LiNbO₃), potassium niobate (KNbO₃), lithium tetraborate (Li₂B₄O₇), barium titanate (BaTiO₃), and PZT (lead zirconate titanate). It is desirable to use AlN or ZnO.

Among the materials, as the material forming each of the piezoelectric layers 412 and 422, it is desirable to use ZnO or AlN. ZnO and AlN are materials having low dielectric constants. Therefore, it is possible to reduce parasitic capacitance in detection. These materials can be deposited by the reactive sputtering method.

Average thickness of each of the piezoelectric layers 412 and 422 is desirably 50 to 3000 nm and more desirably 200 to 2000 nm. Consequently, it is possible to improve the detection characteristic of the detecting sections 41 and 42 while preventing the piezoelectric layers 412 and 422 from adversely affecting the vibration characteristic of the vibrating arm for detection 23.

Each of the second electrode layers 413 and 423 can be formed of, for example, a metal material such as gold (Au), a gold alloy, platinum (Pt), aluminum (Al), an aluminum alloy, silver (Ag), a silver alloy, chrome (Cr), a chrome alloy, copper (Cu), molybdenum (Mo), niobium (Nb), tungsten (W), iron (Fe), titanium (Ti), cobalt (Co), zinc (Zn), or zirconium (Zr) or a transparent electrode material such as ITO or ZnO.

An average thickness of each of the second electrode layers 413 and 423 is not specifically limited. However, for example, the average thickness is desirably about 1 to 300 nm and more desirably 10 to 200 nm. Consequently, it is possible to improve the electrical conductivity of the second electrode layers 413 and 423 while preventing the second electrode layers 413 and 423 from adversely affecting the detection characteristic of the detecting sections 41 and 42 and the vibration characteristic of the vibrating arm for detection 23.

An insulator layer (an insulative protection layer) having a function of protecting the piezoelectric layer 412 and preventing a short circuit between the first electrode layer 411 and the second electrode layer 413 may be provided between the piezoelectric layer 412 and the second electrode layer 413. Similarly, an insulator layer may be provided between the piezoelectric layer 422 and the second electrode layer 423.

The insulator layer is formed of, for example, SiO₂ (silicon oxide), AlN (aluminum nitride), or SiN (silicon nitride).

A base layer having a function of preventing the second electrode layer 413 from peeling from the piezoelectric layer 412 (when the insulator layer is provided, the insulator layer) may be provided between the piezoelectric layer 412 and the second electrode layer 413. Similarly, a base layer may be provided between the piezoelectric layer 422 and the second electrode layer 423.

The base layer is formed of, for example, Ti or Cr.

When the vibrating arm for detection 23 undergoes bending vibration in the x-axis direction, one of the detecting sections 41 and 42 expands in the y-axis direction and the other contracts in the y-axis direction to output charges.

Similarly, when the vibrating arm for detection 24 undergoes bending vibration in the x-axis direction, one of the detecting sections 43 and 44 expands in the y-axis direction and the other contracts in the y-axis direction to output charges.

In the detecting sections 41 and 42, as shown in FIGS. 4B and 6A, the first electrode layer 411 of the detecting section 41 and the first electrode layer 421 of the detecting section 42 are electrically connected to each other.

Consequently, it is possible to electrically connect the detecting section 41 and the detecting section 42 in series as explained later and detect charges from the detecting sections 41 and 42.

In particular, in this embodiment, the first electrode layer 411 of the detecting section 41 and the first electrode layer 421 of the detecting section 42 are integrally formed to configure a common electrode. The first electrode layers 411 and 421 are electrically connected to each other by the vibrating arm for detection 23. Consequently, with a relatively simple configuration, it is possible to electrically connect the detecting section 41 and the detecting section 42 in series.

The second electrode layer 413 of the detecting section 41 is electrically connected to the terminal 62 (a first terminal for detection). The second electrode layer 423 of the detecting section 42 is electrically connected to the terminal 63 (a second terminal for detection).

Similarly, although not shown in the figure, the first electrode layer of the detecting section 43 and the first electrode layer of the detecting section 44 are electrically connected to each other. The second electrode layer of the detecting section 43 is electrically connected to a terminal 65. The second electrode layer of the detecting section 44 is electrically connected to a terminal 66.

### Terminals

The terminals 61 to 63 are provided on the fixed section 221 of the supporting section 22. The terminals 64 to 66 are provided on the fixed section 222 of the supporting section 22.

The terminals 61 to 66, wires (not shown in the figure), and the like can be formed of, for example, a metal material such as gold (Au), a gold alloy, platinum (Pt), aluminum (Al), an aluminum alloy, silver (Ag), a silver alloy, chrome (Cr), a chrome alloy, copper (Cu), molybdenum (Mo), niobium (Nb), tungsten (W), iron (Fe), titanium (Ti), cobalt (Co), zinc (Zn), or zirconium (Zr) or a transparent electrode material such as ITO or ZnO. The terminals 61 to 66, the wires, and the like can be collectively formed simultaneously with the first electrode layers or the second electrode layers of the detecting sections 41 to 44 and the driving sections 51 to 58.

The sensor element 2 configured as explained above detects angular velocity CO around the z axis as explained below.

First, a voltage (a driving signal) is applied between the terminal 61 and the terminal 64, whereby, as shown in FIG. 5A, the vibrating arm for driving 25 and the vibrating arm for driving 27 are subjected to bending vibration (driving vibration) to approach and separate from each other in directions indicated by an arrow A in the figure and the vibrating arm for driving 26 and the vibrating arm for driving 28 are subjected to bending vibration (driving vibration) to approach and separate from each other in directions same as the directions of the bending vibration.

At this point, if angular velocity is not applied to the sensor element 2, since the vibrating arms for driving 25 and 26 and the vibrating arms for driving 27 and 28 are surface-symmetrically vibrating with respect to a yz plane that passes the center point (the center of gravity G), the base 21 (the main body section 211 and the coupling arms 212 and 213) and the vibrating arms for detection 23 and 24 hardly vibrate.

In a state in which the vibrating arms for driving 25 to 28 are subjected to driving vibration in this way, when the angular velocity ω around a normal that passes the center of gravity G is applied to the sensor element 2, Coriolis forces respectively act on the vibrating arms for driving 25 to 28. Consequently, as shown in FIG. 5B, the coupling arms 212 and 213 undergo bending vibration in directions indicated by an arrow B in the figure. According to the bending vibration, in the vibrating arms for detection 23 and 24, bending vibration (detection vibration) in directions indicated by an arrow C in the figure is excited to cancel the bending vibration.

Charges generated in the detecting sections 41 and 42 by the bending vibration of the vibrating arm for detection 23 are output from the terminals 62 and 63. Charges generated in the detecting sections 43 and 44 by the bending vibration of the vibrating arm for detection 24 are output from the terminals 65 and 66.

The angular velocity ω applied to the sensor element 2 can be calculated on the basis of the charges output from the terminals 62, 63, 65, and 66 in this way.

At this point, as shown in FIG. 6A, the detecting sections 41 and 42 are electrically connected in series. Similarly, the detecting sections 43 and 44 are electrically connected in series. Therefore, it is possible to reduce noise due to the parasitic capacitance of the detecting sections 41 to 44. As a result, it is possible to improve the detection sensitivity of the sensor element 2.

The detecting sections 41 and 42 are representatively specifically explained. A noise amount due to the parasitic capacitance of the detecting sections 41 and 42 is proportional to the capacitance of the detecting sections 41 and 42.

When the capacitance of each of the detecting sections 41 and 42 is represented as Co, the electrode area of each of the detecting sections 41 and 42 is represented as A, the thickness (the inter-electrode distance) of the piezoelectric layers of each of the detecting sections 41 and 42 is represented as t, and the dielectric constant of the piezoelectric material of each of the detecting sections 41 and 42 is represented as ∈, Co=∈×A/2t.

On the other hand, in the past, as shown in FIG. 6B, a detecting section 141 and a detecting section 142 are electrically connected to an IC chip 103 in parallel. Specifically, each of a first electrode layer 1411 of the detecting section 141 and a second electrode layer 1423 of the detecting section 142 is electrically connected to a terminal 163. Each of a second electrode layer 1413 of the detecting section 141 and a first electrode layer 1421 of the detecting section 142 is electrically connected to a terminal 162. The terminals 162 and 163 are electrically connected to the IC chip 103.

When the detecting sections 141 and 142 are connected in parallel in this way, a charge amount (a signal amount) to be output is about twice as large as a charge amount output when the detecting sections 41 and 42 are connected in series as explained above.

However, when the capacitance of each of the detecting sections 141 and 142 is represented as Co, the electrode area of each of the detecting sections 141 and 142 is represented as A, and the thickness (the inter-electrode distance) of the piezoelectric layer of each of the detecting sections 141 and 142 is represented as t, and the dielectric constant of the piezoelectric material of each of the detecting sections 141 and 142 is represented as ∈, Co=2×∈×A/t. In other words, when the detecting sections 141 and 142 are connected in parallel, noise due to parasitic capacitance is about four times as large as noise that occurs when the detecting sections 41 and 42 are connected in series.

Therefore, by electrically connecting the detecting sections 41 and 42 in series, it is possible to increase an S/N ratio to about twice an S/N ratio obtained when the detecting sections 141 and 142 are electrically connected in parallel as in the past. As a result, it is possible to improve the detection sensitivity of the sensor element 2.

### IC Chip 3

The IC chip 3 shown in FIGS. 1 and 2 is an electronic component having a function of driving the sensor element 2 explained above and a function of detecting an output (a sensor output) from the sensor element 2.

Although not shown in the figures, the IC chip 3 includes a driving circuit that drives the sensor element 2 and a detecting circuit that detects an output (charges) from the sensor element 2 (more specifically, the detecting sections 41 to 44).

The second electrode layer 413 (the first upper electrode layer) of the detecting section 41 and the second electrode layer 423 (the second upper electrode layer) of the detecting section 42 are electrically connected to the detecting circuit (see FIG. 6A). Consequently, it is possible to electrically connect the detecting sections 41 and 42 to the detecting circuit in series and detect charges from the detecting sections 41 and 42.

Similarly, the detecting sections 43 and 44 are also electrically connected to the detecting circuit in series.

A plurality of connection terminals 31 are provided in the IC chip 3.

### Package

The package 9 houses the sensor element 2 and the IC chip 3.

The package 9 includes a base 91 including a recess opened on the upper surface thereof and a lid (a cover) 42 joined to the base 91 to close the opening of the recess of the base 91. The package 9 includes a housing space S on the inner side thereof. The sensor element 2 and the IC chip 3 are hermetically housed and set in the housing space S.

A plurality of internal terminals 71 and a plurality of internal terminals 72 are provided on the upper surface of the base 91.

The terminals 61 to 66 of the sensor element 2 are electrically connected to the plurality of internal terminals 71 via a conductive fixing members 81 such as solder, silver paste, or a conductive adhesive (an adhesive obtained by dispersing a conductive filler such as metal particles in a resin material). The sensor element 2 is fixed to the base 91 by the conductive fixing member 81.

The plurality of internal terminals 71 are electrically connected to the plurality of internal terminals 72 via not-shown wires.

The plurality of connection terminals 31 of the IC chip 3 are electrically connected to the plurality of internal terminals 72 via wires formed by, for example, bonding wires.

The IC chip 3 is joined to the upper surface of the base 91 by a joining member 82 such as an adhesive including, for example, epoxy resin or acrylic resin. Consequently, the IC chip 3 is supported by and fixed to the base 91.

Although not shown in the figures, a plurality of external terminals used when the sensor device 1 is mounted on an apparatus (an external apparatus) are provided on the lower surface of the base 91 (the bottom surface of the package 9).

The plurality of external terminals are electrically connected to the internal terminals 72 via not-shown internal wires.

Each of the internal terminals 71 and 72 and the like is formed of a metal film obtained by, for example, laminating a film of nickel (Ni), gold (Au), or the like on a metalized layer of tungsten (W) or the like through plating or the like.

The lid 92 is hermetically joined to the base 91. Consequently, the package 9 is hermetically sealed.

The lid 92 is formed of, for example, a material same as the material of the base 91 or metal such as Kovar, 42 alloy, or stainless steel.

A method of joining the base 91 and the lid 92 is not specifically limited. For example, a joining method by an adhesive formed of a solder material or hardening resin or a welding method such as seam welding or laser welding can be used.

The package 9 can be retained in a decompressed state or an inert gas encapsulated state by performing the joining under decompression or under an inert gas atmosphere.

With the sensor device 1 according to the first embodiment explained above, it is possible to electrically connect the detecting section 41 and the detecting section 42 in series, connect the detecting section 43 and the detecting section 44 in series, and detect charges from the detecting sections 41 to 44. Therefore, it is possible to reduce parasitic capacitance to about a quarter compared with parasitic capacitance generated when the two detecting sections are electrically connected in parallel as in the past. As a result, it is possible to improve the detection sensitivity of the sensor element 2.

Since it is unnecessary to subject the vibrating arms for detection 23 and 24 to driving vibration, with a relatively simple configuration, it is possible to electrically connect the lower electrode layers of the detecting sections 41 and 42 each other via the vibrating arm for detection 23 and electrically connect the lower electrode layers of the detecting sections 43 and 44 each other via the vibrating arm for detection 24.

The sensor device 1 including the sensor element 2 is excellent in reliability.

### Second Embodiment

A sensor device according to a second embodiment of the invention is explained.

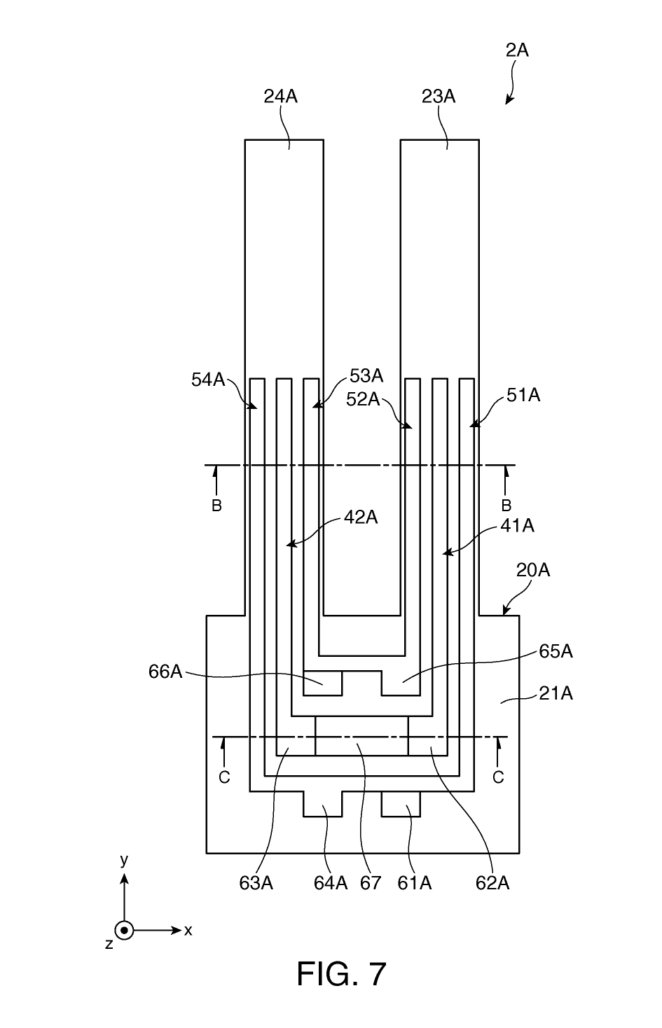

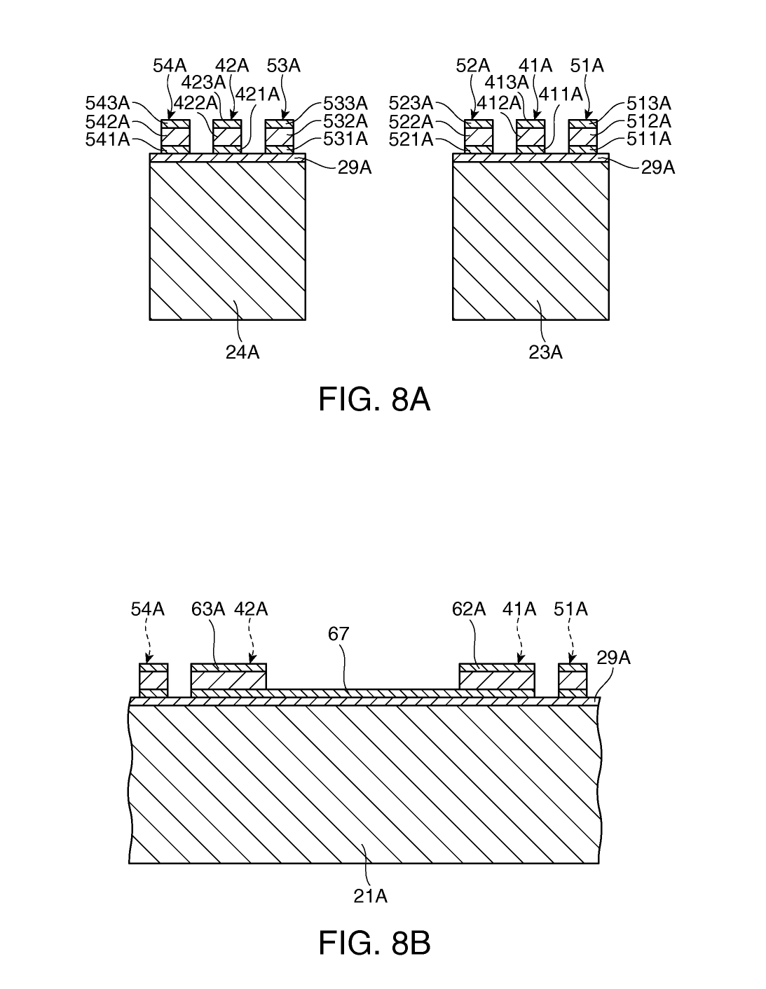

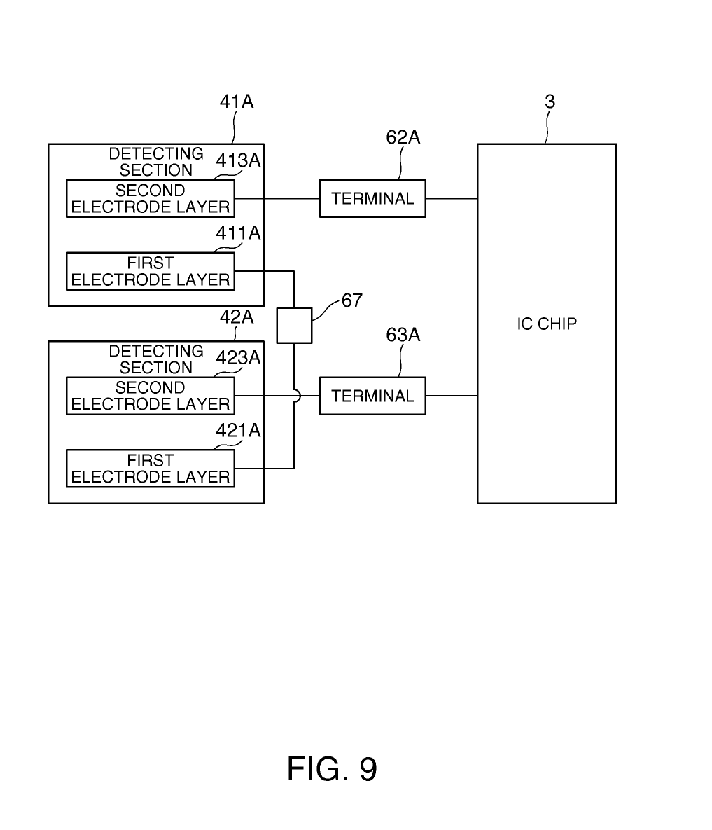

FIG. 7 is a plan view of a sensor element of the sensor device according to the second embodiment of the invention. FIG. 8A is a sectional view taken along line B-B in FIG. 7. FIG. 8B is a sectional view taken along line C-C in FIG. 7. FIG. 9 is a block diagram for explaining detecting sections of the sensor element shown in FIG. 7.

In the following explanation, concerning the sensor device according to the second embodiment, differences from the first embodiment are mainly explained. Explanation of similarities to the first embodiment is omitted.

The sensor device according to the second embodiment is the same as the sensor device according to the first embodiment except that the invention is applied to a sensor element of a bipod tuning fork type. Components same as the components in the first embodiment are denoted by the same reference numerals and signs.

The sensor device according to this embodiment includes a sensor element 2A shown in FIG. 7.

The sensor element 2A includes a vibrating body 20A and driving sections 51A to 54A, detecting sections 41A and 42A, and terminals 61A to 66A provided on the vibrating body 20A.

### Vibrating Body

The vibrating body 20A includes a base 21A and two (a pair of) vibrating arms 23A and 24A.

The two vibrating arms 23A and 24A are provided to extend from the base 21A in parallel to each other. More specifically, each of the two vibrating arms 23A and 24A extends from the base 21A in the y-axis direction (the +y side). The vibrating arms 23A and 24A are provided side by side in the x-axis direction.

Each of the vibrating arms 23A and 24A is formed in a longitudinal shape. Ends (proximal ends) on the base 21A side thereof are fixed ends. Ends (distal ends) on the opposite side of the base 21A are free ends.

The cross sections of the vibrating arms 23A and 24A are formed in a square (see FIG. 8A). The cross section shape of the vibrating arms 23A and 24A is not limited to the square. For example, the vibrating arms 23A and 24A may be formed in an H shape by forming grooves extending along the y-axis direction on the upper surfaces and the lower surfaces of the vibrating arms 23A and 24A.

Weight sections (hammer heads) having a larger cross sectional area (width) than the proximal ends of the vibrating arms 23A and 24A may be provided at the distal ends of the vibrating arms 23A and 24A. In this case, the vibrating body 20A can be further reduced in size and further reduce the resonant frequency of the vibrating arms 23A and 24A.

Adjusting films (weights) for adjusting the resonant frequency of the vibrating arms 23A and 24A may be provided at the distal ends of the vibrating arms 23A and 24A.

As a material forming the vibrating body 20A, a material same as the material forming the vibrating body 20 according to the first embodiment can be used.

In the vibrating arm 23A (a first vibrating arm) of the vibrating body 20A, the pair of driving sections 51A and 52A and the detecting section 41A (a first detecting section) are provided. Similarly, in the vibrating arm 24A (a second vibrating arm), the pair of driving sections 53A and 54A and the detecting section 42A (a second detecting section) are provided.

In this embodiment, as shown in FIGS. 8A and 8B, an insulator layer 29A is provided on the upper surface of the vibrating body 20A. The insulator layer 29A can be formed the same as the insulator layer 29 in the first embodiment.

The pair of driving sections 51A and 52A subject the driving arm 23A to bending vibration in the x-axis direction. Similarly, the pair of driving sections 53A and 54A subject the vibrating arm 24A to bending vibration in the x-axis direction.

The driving section 51A is provided on one side (the right side in FIG. 7) in the width direction of the vibrating arm 23A (the x-axis direction). The driving section 52A is provided on the other side (the left side in FIG. 7).

Similarly, the driving section 53A is provided on one side (the right side in FIG. 7) in the width direction of the vibrating arm 24A (the x-axis direction). The driving section 54A is provided on the other side (the left side in FIG. 7).

In this embodiment, the driving sections 51A and 52A are mainly provided in a section on the proximal end side of the vibrating arm 23A. Similarly, the driving sections 53A and 54A are mainly provided in a section on the proximal end side of the vibrating arm 24A.

The driving sections 51A to 54A are configured to expand and contract in the y-axis direction through energization.

More specifically, as shown in FIG. 8A, the driving section 51A is configured by laminating a first electrode layer 511A, a piezoelectric layer (a piezoelectric thin film) 512A, and a second electrode layer 513A on the vibrating arm 23A in this order.

Similarly, the driving section 52A is configured by laminating a first electrode layer 521A, a piezoelectric layer (a piezoelectric thin film) 522A, and a second electrode layer 523A on the vibrating arm 23A in this order. The driving section 53A is configured by laminating a first electrode layer 531A, a piezoelectric layer (a piezoelectric thin film) 532A, and a second electrode layer 533A on the vibrating arm 24A in this order. The driving section 54A is configured by laminating a first electrode layer 541A, a piezoelectric layer (a piezoelectric thin film) 542A, and a second electrode layer 543A on the vibrating arm 24A in this order.

The driving sections 51A to 54A can be formed the same as the driving sections 51 to 58 in the first embodiment.

In the driving section 51A configured as explained above, when a voltage is applied between the first electrode layer 511A and the second electrode layer 513A, an electric field in the z-axis direction is generated in the piezoelectric layer 512A. The piezoelectric layer 512A expands or contracts in the y-axis direction. Similarly, in the driving section 52A, when a voltage is applied between the first electrode layer 521A and the second electrode layer 523A, an electric field in the z-axis direction is generated in the piezoelectric layer 522A. The piezoelectric layer 522A expands or contracts in the y-axis direction.

At this point, when one of the driving sections 51A and 52A is caused to expand in the y-axis direction, the other is caused to contract in the y-axis direction. Consequently, the vibrating arm 23A can be subjected to bending vibration in the x-axis direction.

Similarly, the vibrating arm 24A can be subjected to bending vibration in the x-axis direction by the driving sections 53A and 54A.

In this embodiment, each of the first electrode layer 511A of the driving section 51A and the first electrode layer 541A of the driving section 54A is electrically connected to the terminal 61A provided in the base 21A shown in FIG. 7. Each of the second electrode layer 513 of the driving section 51A and the second electrode layer 543A of the driving section 54A is electrically connected to the terminal 64A provided in the base 21A shown in FIG. 7. Each of the first electrode layer 521A of the driving section 52A and the first electrode layer 531A of the driving section 53A is electrically connected to the terminal 66A provided in the base 21A shown in FIG. 7. Each of the second electrode layer 523A of the driving section 52A and the second electrode layer 533A of the driving section 53A is electrically connected to the terminal 65 provided in the base 21A shown in FIG. 7.

Therefore, it is possible to subject the vibrating arms 23A and 24A to bending vibration in the x-axis direction to approach or separate from each other by applying a voltage between the terminals 61A and 65A and the terminals 64A and 66A while setting the terminal 61A and the terminal 65A to the same potential and setting the terminal 64A and the terminal 66A to the same potential.

On the other hand, the detecting section 41A detects bending vibration (so-called out-of-plane vibration) in the z-axis direction of the vibrating arm 23A. Similarly, the detecting section 42A detects bending vibration in the z-axis direction of the vibrating arm 24A.

The detecting section 41A is provided in the center in the width direction of the vibrating arm 23A (the x-axis direction). Similarly, the detecting section 42A is provided in the center in the width direction of the vibrating arm 24A (the x-axis direction).

In this embodiment, the detecting section 41A is mainly provided in a section on the proximal end side of the vibrating arm 23A. Similarly, the detecting section 42A is mainly provided in a section on the proximal end side of the vibrating arm 24A.

The detecting section 41A is provided between the pair of driving sections 51A and 52A. Similarly, the detecting section 42A is provided between the pair of driving sections 53A and 54A.

The detecting sections 41A and 42A are configured to output charges by expanding and contracting in the y-axis direction.

Specifically, as shown in FIG. 8A, the detecting section 41A (the first detecting section) includes a first electrode layer 411A (a first lower electrode layer), a second electrode layer 413A (a first upper electrode layer) provided on the opposite side of the vibrating arm 23A with respect to the first electrode layer 411A, and a piezoelectric layer 412A (a first piezoelectric layer) provided between the first electrode layer 411A and the second electrode layer 413A. In other words, the detecting section 41A is configured by laminating the first electrode layer 411A, the piezoelectric layer (a piezoelectric thin film) 412A, and the second electrode layer 413A on the vibrating arm 23A in this order.

Similarly, the detecting section 42A (the second detecting section) is configured by laminating a second electrode layer 421A (a second lower electrode layer), a piezoelectric layer (a piezoelectric thin film) 422A (a second piezoelectric layer), and a second electrode layer 423A (a second upper electrode layer) on the vibrating arm 24A in this order.

The detecting sections 41A and 42A can be formed the same as the detecting sections 41 to 43 in the first embodiment.

The detecting section 41A configured as explained above expands or contracts in the y-axis direction and outputs charges when the vibrating arm 23A bends in the z-axis direction. Consequently, the detecting section 41A outputs charges according to bending vibration in the z-axis direction of the vibrating arm 23A.

Similarly, the detecting section 42A outputs charges according to bending vibration in the z-axis direction of the vibrating arm 24A.

In this embodiment, the first electrode layer 411A of the detecting section 41A and the first electrode layer 421A of the detecting section 42A are electrically connected to each other via a conductor section 67 provided in the base 21A shown in FIG. 7.

As explained above, the first electrode layer 411A of the detecting section 41A and the first electrode layer 421A of the detecting section 42A are electrically connected to each other by the base 21A. Consequently, with a relatively simple configuration, it is possible to electrically connect the detecting sections 41A and 42A in series.

In particular, in the sensor element 2A, the driving sections and the detecting sections are provided in the vibrating arms. Therefore, an effect realized by electrically connecting the first electrode layer 411A of the detecting section 41A and the first electrode layer 421A of the detecting section 42A via the base 21A is conspicuous.

In this embodiment, the conductor section 67 is formed integrally with the first electrode layer 411A and the first electrode layer 421A. The conductor section 67 can be formed in a film forming process and formed of a material same as the film forming process for and the material of the first electrode layer 411A and the first electrode layer 421A.

The second electrode layer 413A of the detecting section 41A is electrically connected to the terminal 62A (a first terminal for detection) provided in the base 21A shown in FIG. 7. The second electrode layer 423A of the detecting section 42A is electrically connected to the terminal 63A (a second terminal for detection) provided in the base 21A shown in FIG. 7. Consequently, with a relatively simple configuration, it is possible to electrically connect the detecting section 41A and the detecting section 42A in series and detect charges from the detecting sections 41A and 42A.

In the sensor element 2A configured as explained above, in a state in which the vibrating arms 23A and 24A are subjected to bending vibration (driving vibration) in the x-axis direction to approach or separate from each other as explained above, when the angular velocity WI around the y axis is applied to the sensor element 2A, the vibrating arms 23A and 24A undergo bending vibration (detection vibration) to opposite sides each other in the z-axis direction with Coriolis forces.

It is possible to calculate the angular velocity ω applied to the sensor element 2A by detecting charges generated in the detecting sections 41A and 42A by the detection vibration of the vibrating arms 23A and 24A.

Therefore, when the vibrating arms 23A and 24A undergo bending vibration to the opposite sides each other in the z-axis direction, a potential difference occurs between the terminal 61A and the terminal 64A.

At this point, as shown in FIG. 9, the detecting sections 41A and 42A are electrically connected to the IC chip 3 in series. Therefore, it is possible to reduce noise due to the parasitic capacitance of the detecting sections 41A and 42A. As a result, it is possible to improve the detection sensitivity of the sensor element 2A.

### Electronic Apparatus

Electronic apparatuses excellent in reliability can be provided by incorporating the sensor device explained above in the electronic apparatuses.

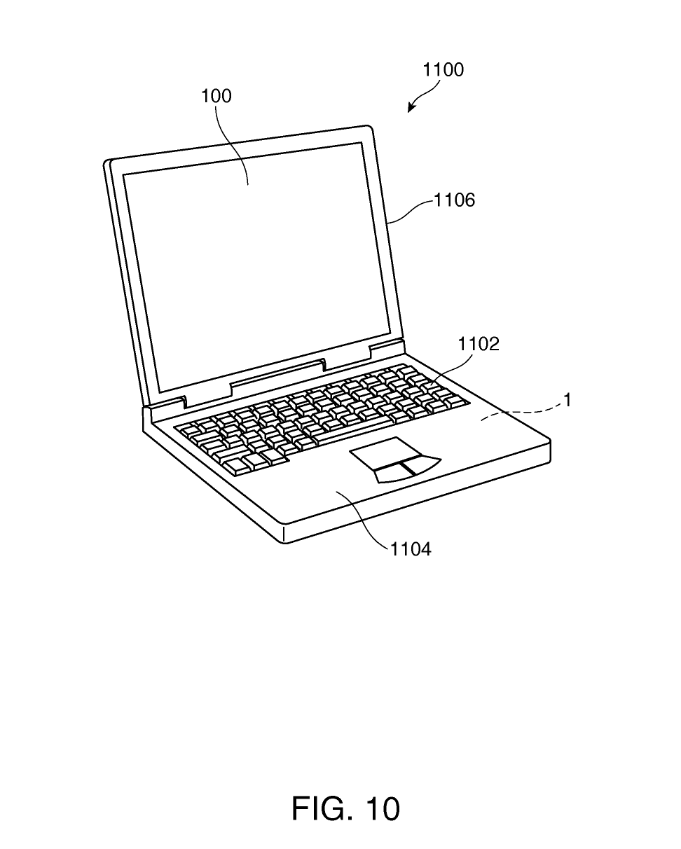

An example of an electronic apparatus including the sensor device according to an embodiment of the invention is explained in detail below with reference to FIGS. 10 to 12.

FIG. 10 is a perspective view showing the configuration of a mobile (or notebook) personal computer to which the electronic apparatus according to the embodiment of the invention is applied.

In the figure, a personal computer 1100 includes a main body section 1104 including a keyboard 1102 and a display unit 1106 including a display section 100. The display unit 1106 is pivotably supported with respect to the main body section 1104 via a hinge structure section.

In the personal computer 1100, the sensor device 1 functioning as the gyro sensor is incorporated.

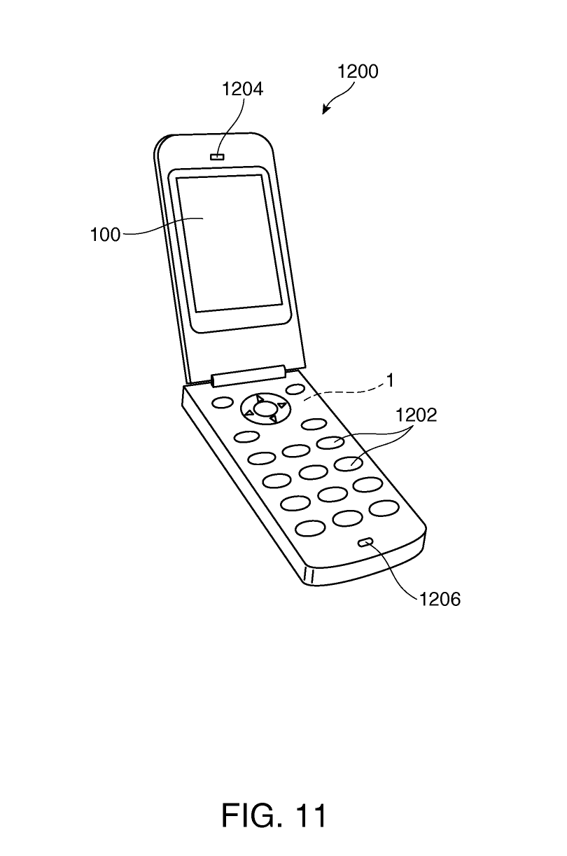

FIG. 11 is a perspective view showing the configuration of a cellular phone (including a PHS) to which the electronic apparatus according to the embodiment of the invention is applied.

In the figure, a cellular phone 1200 includes a plurality of operation buttons 1202, an earpiece 1204, and a mouthpiece 1206. The display section 100 is arranged between the operation buttons 1202 and the earpiece 1204.

In the cellular phone 1200, the sensor device 1 functioning as the gyro sensor is incorporated.

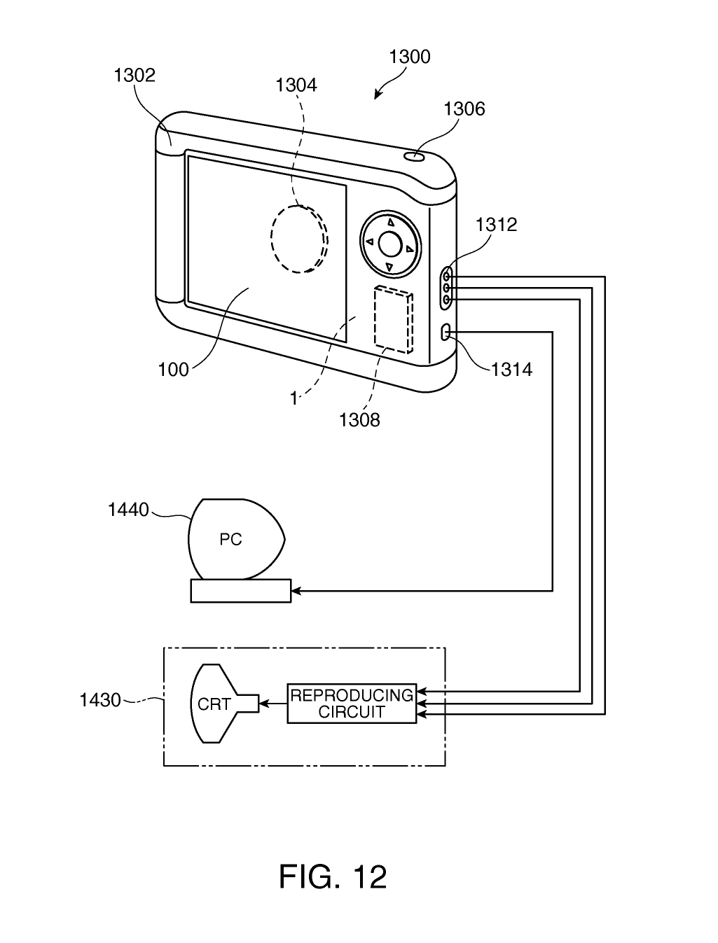

FIG. 12 is a perspective view showing the configuration of a digital still camera to which the electronic apparatus according to the embodiment of the invention is applied. In the figure, connection to external apparatuses is briefly shown.

A normal camera exposes a silver-halide photograph film to a light image of a subject. On the other hand, a digital still camera 1300 photoelectrically converts the light image of the subject using an image pickup device such as a CCD (Charge Coupled Device) and generates an image pickup signal (an image signal).

A display section is provided on the back of a case (a body) 1302 of the digital still camera 1300 to display an image on the basis of the image pickup signal generated by the CCD. The display section functions as a finder that displays the subject as an electronic image.

A light receiving unit 1304 including an optical lens (an image pickup optical system) and a CCD is provided on the front side of the case 1302 (the rear side in the figure).

When a photographer checks a subject image displayed on the display section and depresses a shutter button 1306, an image pickup signal of the CCD at that point is transferred to and stored in a memory 1308.

In the digital still camera 1300, a video signal output terminal 1312 and an input and output terminal 1314 for data communication are provided on a side of the case 1302. A television monitor 1430 and a personal computer 1440 are respectively connected to the video signal output terminal 1312 and the input and output terminal 1314 for data communication according to necessity. Further, the image pickup signal stored in the memory 1308 is output to the television monitor 1430 and the personal computer 1440 by predetermined operation.

In the digital still camera 1300, the sensor device 1 functioning as the gyro sensor is incorporated.

Besides the personal computer (the mobile personal computer) shown in FIG. 10, the cellular phone shown in FIG. 11, and the digital still camera shown in FIG. 12, the electronic apparatus according to the embodiment of the invention can be applied to, according to types of electronic devices, for example, a vehicle body posture detecting apparatus, a pointing device, a head mount display, an inkjet ejecting apparatus (e.g., an inkjet printer), a laptop personal computer, a television, a video camera, a videotape recorder, a navigation apparatus, a pager, an electronic notebook (including an electronic notebook with a communication function), an electronic dictionary, an electric calculator, an electronic game apparatus, a game controller, a word processor, a workstation, a television telephone, a security television monitor, an electronic binocular, a POS terminal, medical equipment (e.g., an electronic thermometer, a sphygmomanometer, a blood glucose monitoring system, an electrocardiogram measuring apparatus, an ultrasonic diagnosis apparatus, and an electronic endoscope), a fish finder, various measurement apparatuses, meters (e.g., meters of a vehicle, an airplane, and a ship), a flight simulator, and the like.

The sensor elements, the sensor devices, and the electronic apparatuses according to the embodiments of the invention are explained above with reference to the drawings. However, the invention is not limited to the embodiments. The components of the sections can be replaced with arbitrary components having the same functions. Other arbitrary components may be added. The sensor devices according to the embodiments of the invention may be a sensor device obtained by combining arbitrary two or more configurations (characteristics) in the embodiments.

In the explanation in the embodiments, the first lower electrode layer of the first detecting section and the second lower electrode layer of the second detecting section are electrically connected to each other. However, the first upper electrode layer of the first detecting section and the second upper electrode layer of the second detecting section may be electrically connected to each other. In this case, the first lower electrode layer of the first detecting section and the second lower electrode layer of the second detecting section only have to be electrically connected to the detecting circuit via terminals, respectively.

In the explanation in the embodiments, the driving sections include the piezoelectric elements. However, when the vibrating body is formed of a piezoelectric material, the driving sections may be excitation electrodes provided in the vibrating arms.

The number of vibrating arms included in the sensor element is not limited to the number described in the embodiments. The number of vibrating arms may be one, three to five, or seven or more.

The entire disclosure of Japanese Patent Application No. 2012-042548, filed Feb. 28, 2012 is expressly incorporated by reference herein.

What is claimed is:

1. A sensor element comprising:
a base;
a vibrating arm for detection extended from the base; and
a first detecting section and a second detecting section provided in the vibrating arm for detection and configured to output charges according to vibration of the vibrating arm for detection, wherein
the first detecting section includes a first lower electrode layer, a first upper electrode layer, and a first piezoelectric layer provided between the first lower electrode layer and the first upper electrode layer, the first lower electrode layer being provided above the vibrating arm for detection side,
the second detecting section includes a second lower electrode layer, a second upper electrode layer, and a second piezoelectric layer provided between the second lower electrode layer and the second upper electrode layer, the second lower electrode layer being provided above the vibrating arm for detection side, and
the first lower electrode layer and the second lower electrode layer or the first upper electrode layer and the second upper electrode layer are electrically connected.

2. The sensor element according to claim 1, wherein the first lower electrode layer and the second lower electrode layer are electrically connected to each other by the vibrating arm for detection.

3. The sensor element according to claim 1, further comprising:
a vibrating arm for driving extended from the base; and
a driving section provided in the vibrating arm for driving and configured to subject the vibrating arm for driving to bending vibration.

4. A sensor element comprising:
a base;
a first vibrating arm and a second vibrating arm extended from the base;
a first detecting section provided in the first vibrating arm and configured to output charges according to vibration of the first vibrating arm; and
a second detecting section provided in the second vibrating arm and configured to output charges according to vibration of the second vibrating arm, wherein
the first detecting section includes a first lower electrode layer, a first upper electrode layer, and a first piezoelectric layer provided between the first lower electrode layer and the first upper electrode layer, the first lower electrode layer being provided above the first vibrating arm side,
the second detecting section includes a second lower electrode layer, a second upper electrode layer, and a second piezoelectric layer provided between the second lower electrode layer and the second upper electrode layer, the first lower electrode layer being provided above the first vibrating arm side, and
the first lower electrode layer and the second lower electrode layer or the first upper electrode layer and the second upper electrode layer are electrically connected.

5. The sensor element according to claim 4, wherein the first lower electrode layer and the second lower electrode layer are electrically connected to each other by the base.

6. The sensor element according to claim 4, further comprising:
a first driving section provided in the first vibrating arm and configured to subject the first vibrating arm to bending vibration; and
a second driving section provided in the second vibrating arm and configured to subject the second vibrating arm to bending vibration.

7. The sensor element according to claim 1, further comprising:
a first terminal for detection provided in the base and electrically connected to the first upper electrode layer; and
a second terminal for detection provided in the base and electrically connected to the second upper electrode layer.

8. A sensor device comprising the sensor element according to claim 1.

9. A sensor device comprising the sensor element according to claim 4.

10. The sensor device according to claim 8, further comprising a detecting circuit configured to detect charges from the first detecting section and the second detecting section, wherein
the first lower electrode layer and the second lower electrode layer are electrically connected to each other, and
the first upper electrode layer and the second upper electrode layer are electrically connected to the detecting circuit.

11. The sensor device according to claim 9, further comprising a detecting circuit configured to detect charges from the first detecting section and the second detecting section, wherein
the first lower electrode layer and the second lower electrode layer are electrically connected to each other, and
the first upper electrode layer and the second upper electrode layer are electrically connected to the detecting circuit.

12. An electronic apparatus comprising the sensor element according to claim 1.

13. An electronic apparatus comprising the sensor element according to claim 4.
